(19) United States
(12) Patent Application Publication
(10) Pub. No.: US 2026/0022457 A1
(43) Pub. Date: Jan. 22, 2026

(54) FILM FORMING METHOD AND FILM FORMING APPARATUS

(71) Applicant: Tokyo Electron Limited, Tokyo (JP)

(72) Inventor: Hiroki MURAKAMI, Yamanashi (JP)

(21) Appl. No.: 19/254,665

(22) Filed: Jun. 30, 2025

(30) Foreign Application Priority Data
Jul. 16, 2024 (JP) 2024-113555

(51) Int. Cl. C23C 16/448; C23C 16/455; C23C 16/52

(52) U.S. Cl. CPC C23C 16/448; C23C 16/45527; C23C 16/4557; C23C 16/52

(57) ABSTRACT

A film forming method includes the steps of loading a plurality of substrates into a processing chamber, heating an inside of the processing chamber by a chamber heater provided around the processing chamber, heating a first source gas in a first gas nozzle by a gas heater included in the first gas nozzle, and supplying the heated first source gas from the first gas nozzle into the processing chamber, supplying a first reactive gas that reacts with the first source gas from a second gas nozzle into the processing chamber, and repeating a cycle, including the supplying the first source gas and the supplying the first reactive gas, a plurality of times.

### CROSS-REFERENCE TO RELATED APPLICATIONS

This application is based upon and claims priority to Japanese Patent Application No. 2024-113555, filed on Jul. 16, 2024, the entire contents of which are incorporated herein by reference.

### BACKGROUND

### 1. Field of the Invention

The present disclosure relates to film forming methods, and film forming apparatuses. The film forming method may sometimes be referred to as a film deposition method. The film forming apparatus may sometimes be referred to as a film deposition apparatus.

### 2. Description of the Related Art

There is proposed a technique which forms a silicon oxynitride film on a substrate in a reaction chamber by alternately supplying radicals of dichlorosilane and oxidizing gas into the reaction chamber (for example, refer to Japanese Laid-Open Patent Publication No. 2007-19145). There is proposed a technique which supplies a source gas, that is a vaporized feed gas, into a reaction chamber without condensing the source gas by preheating the source gas with a preheating heater provided in a gas nozzle when supplying the source gas into the reaction chamber from the gas nozzle (for example, refer to Japanese Laid-Open Patent Publication No. 2007-81365).

### SUMMARY

One object of the present disclosure is to provide a technique capable of improving a film deposition rate when forming a silicon-containing film at a low temperature.

According to an aspect of the present disclosure, a film forming method includes loading a plurality of substrates into a processing chamber; heating an inside of the processing chamber by a chamber heater provided around the processing chamber; heating a first source gas in a first gas nozzle by a gas heater included in the first gas nozzle, and supplying the heated first source gas from the first gas nozzle into the processing chamber; supplying a first reactive gas that reacts with the first source gas from a second gas nozzle into the processing chamber; and repeating a cycle, including the supplying the first source gas and the supplying the first reactive gas, a plurality of times.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a vertical sectional view illustrating a film forming apparatus according to an embodiment;

FIG. 2 is a horizontal cross sectional view illustrating the film forming apparatus according to the embodiment;

FIG. 3 is a cross sectional view illustrating an example of a gas nozzle provided in the film forming apparatus according to the embodiment;

FIG. 4 is a timing chart illustrating a film forming method according to a first example of the embodiment;

FIG. 5 is a timing chart illustrating the film forming method according to a second example of the embodiment;

FIG. 6 is a timing chart illustrating the film forming method according to a third example of the embodiment;

FIG. 7 is a diagram illustrating measurement results of a thickness of a silicon nitride film;

FIG. 8 is a diagram illustrating measurement results of a film deposition rate of the silicon nitride film;

FIG. 9 is a diagram illustrating measurement results of a WER of the silicon nitride film; and

FIG. 10 is a diagram illustrating measurement results of a stress of the silicon nitride film.

### DETAILED DESCRIPTION

Hereinafter, non-limiting exemplary embodiments of the present disclosure will be described with reference to the accompanying drawings. In all of the accompanying drawings, the same or corresponding members or parts are designated by the same or corresponding reference numerals, and a redundant description thereof will be omitted.

### [Film Forming Apparatus]

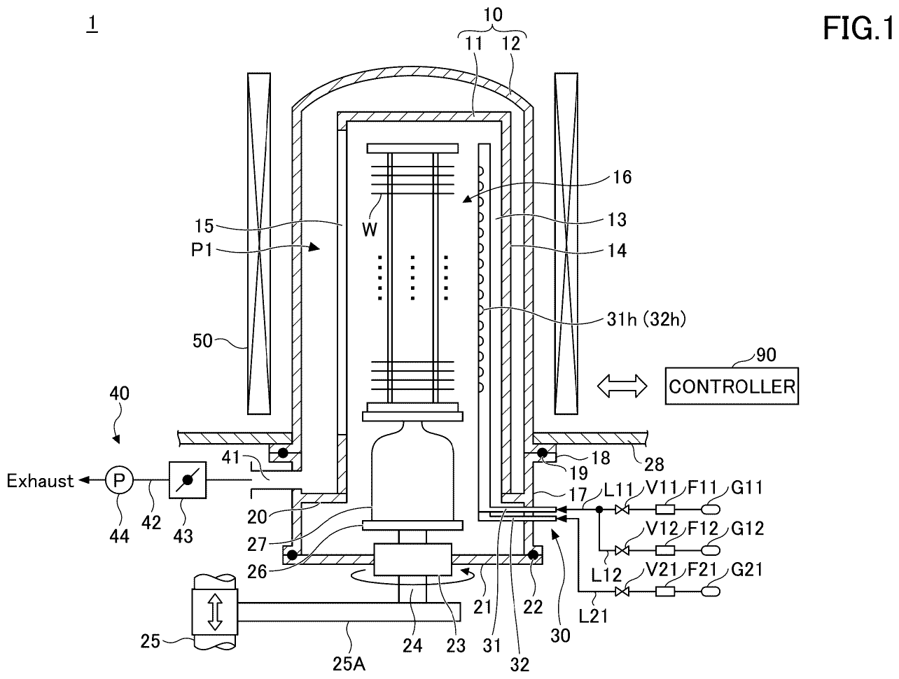

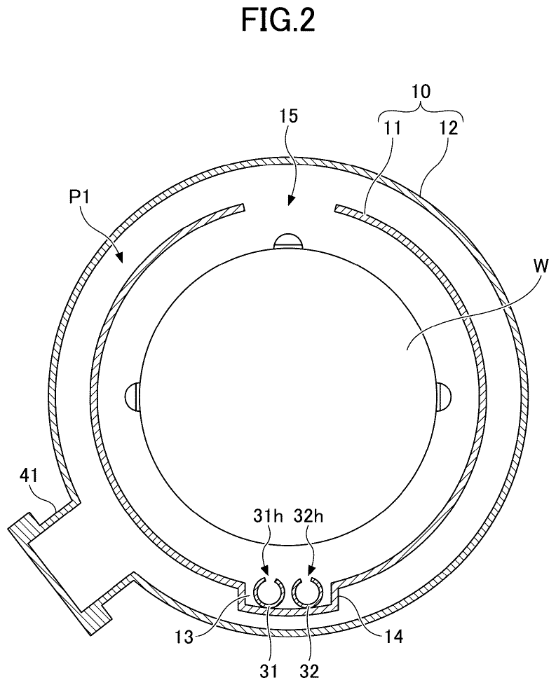

A film forming apparatus 1 according to an embodiment will be described, with reference to FIG. 1 and FIG. 2. FIG. 1 is a vertical cross sectional view illustrating the film forming apparatus 1 according to the embodiment. FIG. 2 is a horizontal cross sectional view illustrating the film forming apparatus 1 according to the embodiment.

The film forming apparatus 1 is a batch type apparatus that performs a process on a plurality of substrates W simultaneously in a single processing cycle. The substrates W are semiconductor wafers, for example. The film forming apparatus 1 includes a processing chamber 10, a gas supply 30, an exhaust 40, a chamber heater 50, and a controller (or a control device) 90.

The inside of the processing chamber 10 can be depressurized. The processing chamber 10 accommodates the substrates W. The processing chamber 10 includes an inner tube 11 and an outer tube 12. The inner tube 11 has a cylindrical shape with a ceiling and an open lower end. The outer tube 12 has a cylindrical shape with a ceiling and an open lower end, and covers an outer side of the inner tube 11. The inner tube 11 and the outer tube 12 are formed of a heat resistant material, such as quartz or the like. The inner tube 11 and the outer tube 12 have a coaxially arranged double tube structure.

A housing 13 that houses a gas supply pipe is formed on a sidewall of the inner tube 11 along a longitudinal direction (a vertical direction). For example, a portion of the sidewall of the inner tube 11 may protrude outward to form a protrusion 14, and the inside of the protrusion 14 may form the housing 13.

A rectangular opening 15 is formed in the sidewall of the inner tube 11 along the longitudinal direction. The opening 15 opposes the housing 13.

The opening 15 is a gas exhaust port formed so as to exhaust the gas inside the inner tube 11. A length of the opening 15 is the same as a length of a boat 16, or is longer than the length of the boat 16, and is formed to extend in the vertical direction.

A lower end of the processing chamber 10 is supported by a cylindrical manifold 17. The manifold 17 is formed of stainless steel, for example. A flange 18 is formed at an upper end of the manifold 17. The flange 18 supports the lower end of the outer tube 12. A seal member 19, such as an O-ring or the like, is provided between the flange 18 and the lower end of the outer tube 12. Thus, the inside of the outer tube 12 is maintained airtight.

An annular support 20 is provided on an inner wall of an upper portion of the manifold 17. The annular support 20 supports the lower end of the inner tube 11. A lid 21 is airtightly attached to an opening at a lower end of the manifold 17 via a seal member 22, such as an O-ring or the like. Accordingly, the opening at the lower end of the processing chamber 10, that is, the opening of the manifold 17 is airtightly closed. The lid 21 is formed of stainless steel, for example.

A rotary shaft 24 penetrates a central portion of the lid 21 via a magnetic fluid seal 23. A lower portion of the rotary shaft 24 is rotatably supported on an arm 25A of an elevator mechanism 25 including a boat elevator.

A rotating plate 26 is provided on an upper end of the rotary shaft 24. The boat 16, which holds the substrates W via a quartz heat insulating stage 27, is placed on the rotating plate 26. The boat 16 is rotated by rotating the rotary shaft 24. The boat 16 is moved up and down integrally with the lid 21, by causing the elevator mechanism 25 to move up and down. Accordingly, the boat 16 is inserted into and removed from the processing chamber 10. The boat 16 can be accommodated inside the processing chamber 10. The boat 16 holds the plurality of substrates W (for example, 50 to 150 substrates W) in a rack configuration (or a tiered arrangement). The boat 16 holds the plurality of substrates W substantially horizontally with a gap in the vertical direction between two adjacent substrates W.

The gas supply 30 supplies various gases into the inner tube 11. The gas supply 30 includes a gas nozzle 31, and a gas nozzle 32. The gas nozzle 31 is an example of a first gas nozzle. The gas nozzle 32 is an example of a second gas nozzle. The gas nozzles 31 and 32 are formed of quartz, for example. The gas supply 30 may further include another gas nozzle.

The gas nozzle 31 is fixed to the manifold 17. The gas nozzle 31 extends linearly along the vertical direction at a position near the inner tube 11, bends in an L-shape inside the manifold 17 to extend in the horizontal direction, and penetrates the manifold 17. A plurality of gas holes 31h are provided in a portion of the gas nozzle 31 located inside the inner tube 11. The gas holes 31h are provided at predetermined intervals along the vertical direction. Each gas hole 31h discharges the gas horizontally toward the substrate W from an outer side in a radial direction of the substrate W. Each gas hole 31h discharges the gas parallel to a principal surface of the substrate W.

A supply path L11 is connected to the gas nozzle 31. The supply path L11 is provided with a supply source G11 of a source gas, a mass flow controller F11, and a valve V11 in this order from an upstream side to a downstream side in the gas flow direction. The source gas includes dichlorosilane (DCS) and ethylene (C₂H₄). The dichlorosilane is an example of a first source gas. The ethylene is an example of a second source gas. A supply timing of the source gas from the supply source G11 is controlled by the valve V11, and a flow rate of the source gas is adjusted to a predetermined flow rate by the mass flow controller F11. The source gas flows into the gas nozzle 31 from the supply path L11, and is discharged into the inner tube 11 from the plurality of gas holes 31h.

A supply path L12 is connected to a downstream side of the valve V11 of the supply path L11. The supply path L12 is provided with a supply source G12 of a purge gas, a mass flow controller F12, and a valve V12 in this order from an upstream side to a downstream side in a gas flow direction. The purge gas includes nitrogen (Ne). A supply timing of the purge gas from the source G12 is controlled by the valve V12, and a flow rate of the purge gas is adjusted to a predetermined flow rate by the mass flow controller F12. The purge gas flows into the gas nozzle 31 from the supply path L12, and is discharged into the inner tube 11 from the plurality of gas holes 31h.

The gas nozzle 32 is fixed to the manifold 17. The gas nozzle 32 extends linearly along the vertical direction at a position near the inner tube 11, bends in an L-shape inside the manifold 17 to extend in the horizontal direction, and penetrates the manifold 17. The gas nozzle 32 is provided side by side with the gas nozzle 31 in a circumferential direction of the inner tube 11. A plurality of gas holes 32h are provided in a portion of the gas nozzle 32 located inside the inner tube 11. The gas holes 32h are provided at predetermined intervals along the vertical direction. Each gas hole 32h discharges the gas horizontally toward the substrate W from the outer side in the radial direction of the substrate W. Each gas hole 32h discharges the gas parallel to the principal surface of the substrate W.

A supply path L21 is connected to the gas nozzle 32. The supply path L21 is provided with a supply source G21 of a reactive gas, a mass flow controller F21, and a valve V21 in this order from an upstream side to a downstream side in a gas flow direction. The reactive gas includes ammonia (NH₃) and ozone (O₃). The ammonia is an example of a first reactive gas. The ozone is an example of a second reactive gas. A supply timing of the reactive gas from the supply source G21 is controlled by the valve V21, and a flow rate of the reactive gas is adjusted to a predetermined flow rate by the mass flow controller F21. The reactive gas flows into the gas nozzle 32 from the supply path L21, and is discharged into the inner tube 11 from the plurality of gas holes 32h.

The exhaust 40 exhausts the gas that is discharged from the inside of the inner tube 11 through the opening 15, and is discharged from a gas outlet 41 through a space P1 between the inner tube 11 and the outer tube 12. The gas outlet 41 is formed in an upper sidewall of the manifold 17 at a position above the annular support 20. An exhaust flow path 42 is connected to the gas outlet 41. A pressure control valve 43 and a vacuum pump 44 are successively provided in the exhaust flow path 42, so that the inside of the processing chamber 10 can be exhausted.

The chamber heater 50 is provided around the outer tube 12. The chamber heater 50 is provided on the base plate 28, for example. The chamber heater 50 has a cylindrical shape so as to cover the outer tube 12. The chamber heater 50 includes a heating element, for example, and heats the inside of the processing chamber 10 and each substrate W inside the processing chamber 10.

The controller 90 may be electronic circuitry (including a processor), such as a central processing unit (CPU), a field programmable gate array (FPGA), an application specific integrated circuit (ASIC), or the like. The electronic circuitry performs the processes of the controller 90 described in the present specification by executing instruction codes or command codes stored in a memory, or by being designed for specialized circuit applications or specific purposes.

### [Gas Nozzle]

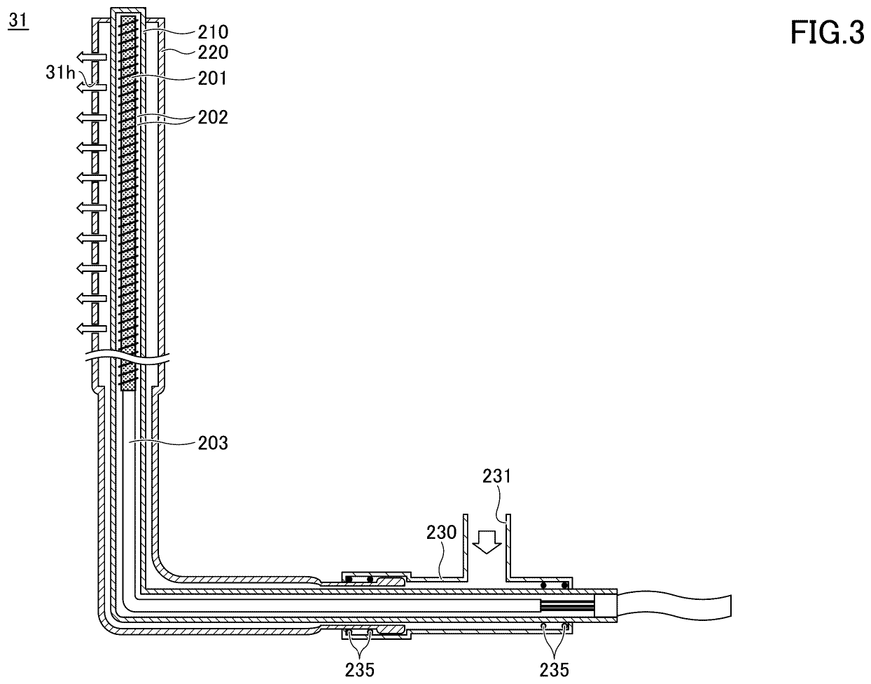

An example of the gas nozzle 31 included in the film forming apparatus 1 will be described with reference to FIG. 3. FIG. 3 is a cross sectional view illustrating the example of the gas nozzle 31 included in the film forming apparatus 1 according to the embodiment.

The gas nozzle 31 includes an inner pipe 210, an outer pipe 220, and an adapter 230. The outer pipe 220 and the adapter 230 are connected via a seal 235. The inner pipe 210 is disposed inside the outer pipe 220 and the adapter 230. An alumina core 201, a heating element 202, and a flexible cable 203 are provided inside the inner pipe 210. The heating element 202 is wound around the alumina core 201. The flexible cable 203 connects the heating element 202 and a heater power supply (not illustrated). The heater power supply supplies power to the heating element 202 via the flexible cable 203. As a result, the heating element 202 generates heat, thereby heating the alumina core 201.

The source gas supplied from a supply port 231 of the adapter 230 passes through a space between the inner pipe 210 and the adapter 230 and a space between the inner pipe 210 and the outer pipe 220, and is discharged from the gas holes 31h. Further, the source gas is heated by supplying power from the heater power source to the heating element 202, and the heated source gas is discharged from the gas holes 31h. As described above, the gas nozzle 31 includes the outer pipe 220 through which the source gas flows, and the gas heater disposed inside the outer pipe 220 to heat the source gas flowing through the outer pipe 220. The gas heater includes the alumina core 201, and the heating element 202. The gas heater is disposed inside the outer pipe 220 that is disposed inside the inner tube 11.

### [Film Forming Method]

### First Example

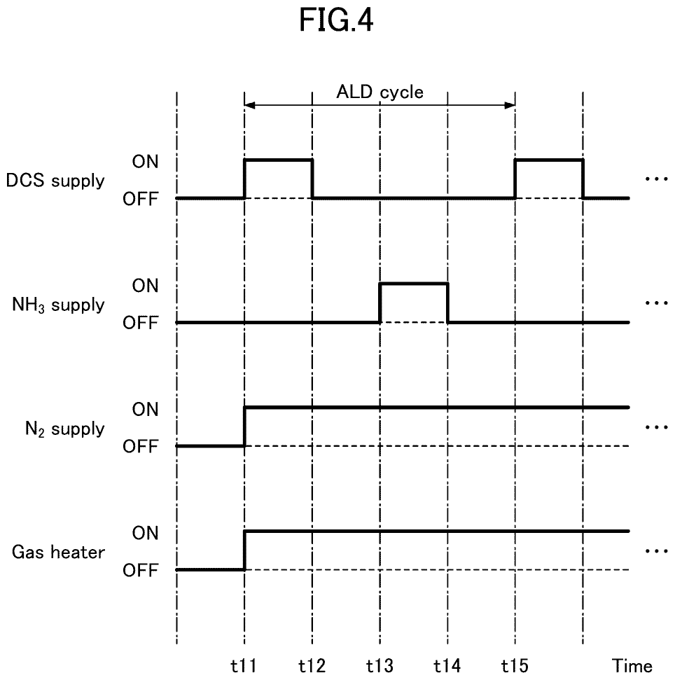

A film forming method according to a first example of the embodiment will be described with reference to FIG. 4. FIG. 4 is a timing chart illustrating a film forming method according to the first example of the embodiment. The film forming method according to the first example is a method of forming a silicon nitride (SiN) film by atomic layer deposition (ALD) in which dichlorosilane and ammonia are supplied non-simultaneously. The film forming method according to the first example is performed under a control of the controller 90.

First, the controller 90 raises the arm 25A to load the boat 16 holding the plurality of substrates W into the processing chamber 10, and closes the opening at the lower end of the processing chamber 10 airtight by the lid 21. Next, the controller 90 controls the exhaust 40 so that the inside of the processing chamber 10 becomes a set pressure, and controls the chamber heater 50 so that the inside of the processing chamber 10 becomes a predetermined temperature.

Next, the controller 90 performs a film forming process of forming a silicon nitride film on a surface of each substrate W inside the processing chamber 10 by atomic layer deposition in which dichlorosilane and ammonia are supplied non-simultaneously.

At a time t11, the gas nozzle 31 starts supplying the dichlorosilane into the inner tube 11. Accordingly, the dichlorosilane is adsorbed on the surface of each substrate W. At the time t11, the gas heater starts heating the gas nozzle 31. Hence, the dichlorosilane is heated in the gas nozzle 31, and supplied into the inner tube 11. A set temperature of the gas heater may be higher than a set temperature of the chamber heater 50, for example. At the time t11, the gas nozzle 31 starts supplying nitrogen into the inner tube 11.

At a time t12, the gas nozzle 31 stops supplying the dichlorosilane into the inner tube 11. The heating of the gas nozzle 31 by the gas heater continues at and after the time t12. The heating of the gas nozzle 31 by the gas heater continues until the film forming process ends, for example. The supplying of the nitrogen from the gas nozzle 31 into the inner tube 11 continues at and after the time t12. During a period from the time t12 to a time t13, the supplying of the nitrogen from the gas nozzle 31 into the inner tube 11 continues. For this reason, residual dichlorosilane inside the inner tube 11 is replaced by the nitrogen. That is, the inside of the inner tube 11 is purged.

At the time t13, the gas nozzle 32 starts supplying the ammonia into the inner tube 11. The ammonia is activated by being heated by the chamber heater 50 when the ammonia flows through the gas nozzle 32. The dichlorosilane adsorbed on the surface of each substrate W is nitrided by the activated ammonia.

At a time t14, the gas nozzle 32 stops supplying the ammonia into the inner tube 11. During a period from the time t14 to a time t15, the supplying of the nitrogen from the gas nozzle 31 into the inner tube 11 continues. For this reason, residual ammonia inside the inner tube 11 is replaced by the nitrogen. That is, the inside of the inner tube 11 is purged.

Next, the processes from the time t11 to the time t15 are regarded as an ALD cycle, and the ALD cycle is repeated a plurality of times. Hence, a silicon nitride film is formed on the surface of each substrate W held by the boat 16.

Next, the controller 90 raises the pressure inside the processing chamber 10 to atmospheric pressure, and lowers the temperature inside the processing chamber 10 to a substrate unloading temperature, before lowering the arm 25A to unload the boat 16 from inside the processing chamber 10. The film forming process with respect to the plurality of substrates W is completed by the processes described above.

According to the film forming method of the first example, the dichlorosilane is activated in the gas nozzle 31 by being heated by the gas heater, and the activated dichlorosilane is supplied into the inner tube 11. Hence, it is possible to improve the reactivity of the dichlorosilane. As a result, it is possible to improve a film deposition rate when forming the silicon nitride film at a low temperature. In addition, because the dichlorosilane in the gas nozzle 31 can be heated by the gas heater that is provided separately from the chamber heater 50, the set temperature of the chamber heater 50 can be low. For this reason, it is possible to reduce a thermal history experienced by each substrate W processed inside the inner tube 11. According to the film forming method of the first example, it is possible to simultaneously reduce the thermal history and improve the reactivity of the dichlorosilane.

In the example illustrated in FIG. 4, the gas nozzle 31 is heated by the gas heater from the time t11 until the film forming process ends, but the timing at which the gas nozzle 31 is heated by the gas heater is not limited thereto. For example, the gas nozzle 31 may be heated by the gas heater at the same timing as the timing at which the gas nozzle 31 supplies the dichlorosilane into the inner tube 11. That is, the gas nozzle 31 may be heated by the gas heater during a period from the time t11 to the time t12. For example, the heating of the gas nozzle 31 by the gas heater may be started before the time t11.

### Second Example

The film forming method according to a second example of the embodiment will be described with reference to FIG. 5. FIG. 5 is a timing chart illustrating the film forming method according to the second example of the embodiment. The film forming method according to the second example differs from the film forming method according to the first example in that a configuration of the second example supplies ozone in place of ammonia. The configuration of the second example of the film forming method is otherwise the same as that of the first example of the film forming method. That is, the second example of the film forming method forms a silicon oxide (SiO₂) film by atomic layer deposition in which dichlorosilane and ammonia are supplied non-simultaneously.

According to second example of the film forming method, the dichlorosilane is activated in the gas nozzle 31 by being heated by the gas heater, and the activated dichlorosilane is supplied into the inner tube 11. Hence, it is possible to improve the reactivity of dichlorosilane. As a result, it is possible to improve a film deposition rate when forming the silicon oxide film at a low temperature. In addition, because the dichlorosilane in the gas nozzle 31 can be heated by the gas heater that is provided separately from the chamber heater 50, the set temperature of the chamber heater 50 can be low. For this reason, it is possible to reduce a thermal history experienced by each substrate W processed inside the inner tube 11. According to the film forming method of the second example, it is possible to simultaneously reduce the thermal history and improve the reactivity of the dichlorosilane.

In the example illustrated in FIG. 5, the gas nozzle 31 is heated by the gas heater from the time t11 until the film forming process ends, but the timing at which the gas nozzle 31 is heated by the gas heater is not limited thereto. For example, the gas nozzle 31 may be heated by the gas heater at the same timing as the timing at which the gas nozzle 31 supplies dichlorosilane into the inner tube 11. That is, the gas nozzle 31 may be heated by the gas heater during a period from the time t11 to the time t12. For example, the heating of the gas nozzle 31 by the gas heater may be started before the time t11.

### Third Example

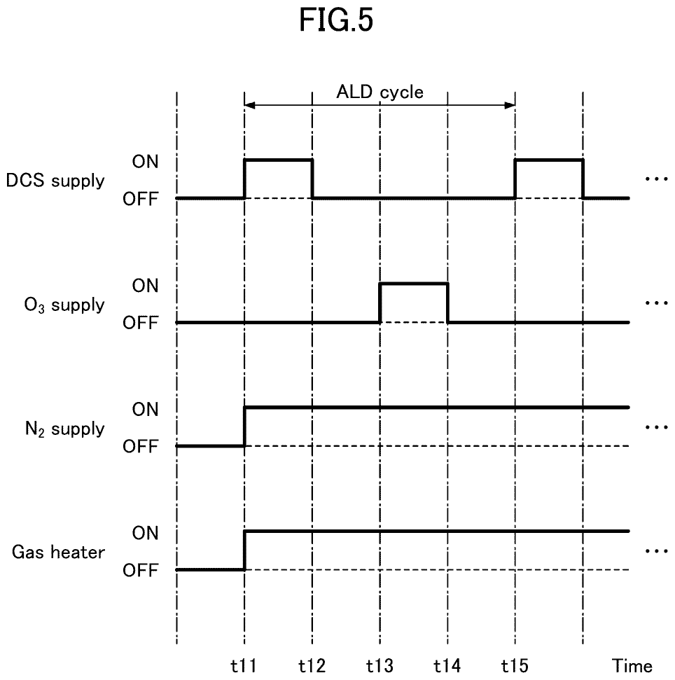

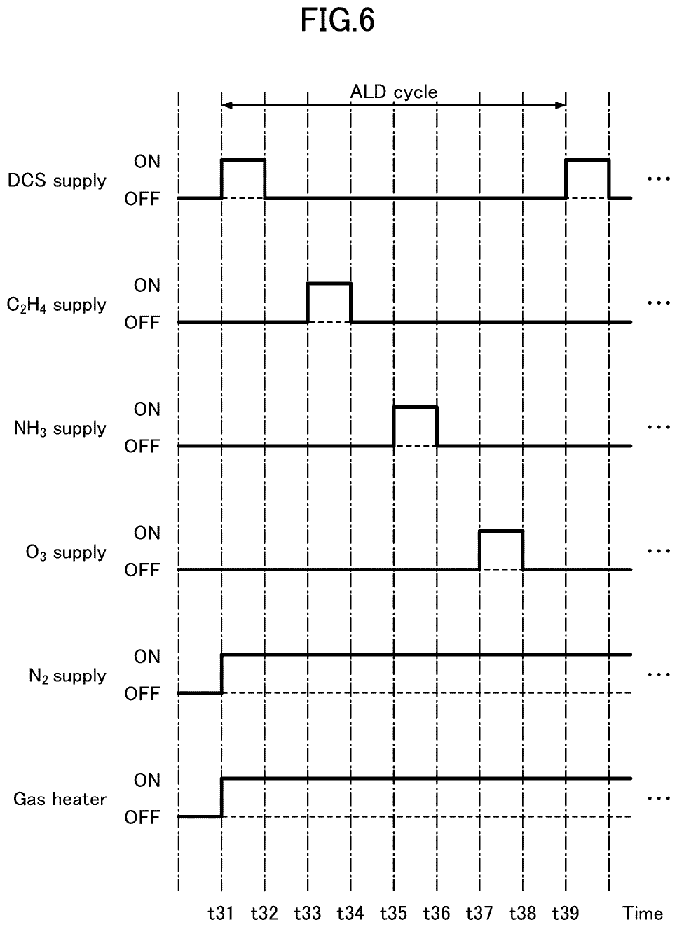

A film forming method according to a third example of the embodiment will be described with reference to FIG. 6. FIG. 6 is a timing chart illustrating a film forming method according to the third example of the embodiment. The film forming method according to the third example is a method of forming a SiOCN film by atomic layer deposition in which dichlorosilane, ethylene, ammonia, and ozone are supplied non-simultaneously. The film forming method according to the third example is performed under the control of the controller 90.

First, the controller 90 raises the arm 25A to load the boat 16 holding the plurality of substrates W into the processing chamber 10, and closes the opening at the lower end of the processing chamber 10 airtight by the lid 21. Next, the controller 90 controls the exhaust 40 so that the inside of the processing chamber 10 becomes a set pressure, and controls the chamber heater 50 so that the inside of the processing chamber 10 becomes a predetermined temperature.

Next, the controller 90 performs a film forming process of forming a SiOCN film on a surface of each substrate W inside the processing chamber 10 by atomic layer deposition in which dichlorosilane, ethylene, ammonia, and ozone are supplied non-simultaneously.

At a time t31, the gas nozzle 31 starts supplying the dichlorosilane into the inner tube 11. Thus, the dichlorosilane is adsorbed on the surface of each substrate W. At the time t31, the gas heater starts to heat the gas nozzle 31. Hence, the dichlorosilane is heated in the gas nozzle 31, and supplied into the inner tube 11. The set temperature of the gas heater may be higher than the set temperature of the chamber heater 50, for example. At the time t31, the gas nozzle 31 starts supplying the nitrogen into the inner tube 11.

At a time t32, the gas nozzle 31 stops supplying the dichlorosilane into the inner tube 11. The heating of the gas nozzle 31 by the gas heater continues at and after the time t32. The heating of the gas nozzle 31 by the gas heater continues until the film forming process ends, for example. The supplying of the nitrogen from the gas nozzle 31 into the inner tube 11 continues at and after the time t32. During a period from the time t32 to a time t33, the supplying of the nitrogen from the gas nozzle 31 into the inner tube 11 continues. For this reason, residual dichlorosilane inside the inner tube 11 is replaced by the nitrogen. That is, the inside of the inner tube 11 is purged.

At the time t33, the gas nozzle 31 starts supplying the ethylene into the inner tube 11. Thus, the ethylene is adsorbed on the surface of each substrate W. In this state, because the heating of the gas nozzle 31 by the gas heater continues, the ethylene is heated in the gas nozzle 31, and supplied into the inner tube 11.

At a time t34, the gas nozzle 31 stops supplying the ethylene into the inner tube 11. During a period from the time t34 to a time t35, the supplying of the nitrogen from the gas nozzle 31 into the inner tube 11 continues. For this reason, residual ethylene inside the inner tube 11 is replaced by the nitrogen. That is, the inside of the inner tube 11 is purged.

At the time t35, the gas nozzle 32 starts supplying the ammonia into the inner tube 11. The ammonia is activated by being heated by the chamber heater 50 when the ammonia flows through the gas nozzle 32. The dichlorosilane and the ethylene adsorbed on the surface of each substrate W are nitrided by the activated ammonia.

At a time t36, the gas nozzle 32 stops supplying the ammonia into the inner tube 11. During a period from the time t36 to a time t37, the supplying of the nitrogen from the gas nozzle 31 into the inner tube 11 continues. For this reason, residual ammonia inside the inner tube 11 is replaced by the nitrogen. That is, the inside of the inner tube 11 is purged.

At the time t37, the gas nozzle 32 starts supplying the ozone into the inner tube 11. The ozone is activated by being heated by the chamber heater 50 when the ozone flows through the gas nozzle 32. The activated ozone oxidizes the dichlorosilane and the ethylene adsorbed on the surface of each substrate W.

At a time t38, the gas nozzle 32 stops supplying the ozone into the inner tube 11. During a period from the time t38 to a time t39, the supplying of the nitrogen from the gas nozzle 31 into the inner tube 11 continues. For this reason, residual ozone inside the inner tube 11 is replaced by the nitrogen. That is, the inside of the inner tube 11 is purged.

Next, the processes from the time t31 to the time t39 are regarded as an ALD cycle, and the ALD cycle is repeated a plurality of times. Thus, a SiOCN film is formed on the surface of each substrate W held by the boat 16.

Next, the controller 90 raises the pressure inside the processing chamber 10 to atmospheric pressure, and lowers the temperature inside the processing chamber 10 to the substrate unloading temperature, before lowering the arm 25A to unload the boat 16 from inside the processing chamber 10. The film forming process with respect to the plurality of substrates W is completed by the processes described above.

According to the film forming method of the third example, the dichlorosilane and the ethylene are activated in the gas nozzle 31 by being heated by the gas heater, and the activated dichlorosilane and ethylene are supplied into the inner tube 11. Hence, it is possible to improve the reactivities of the dichlorosilane and the ethylene. As a result, a film deposition rate when forming the SiOCN film at a low temperature. In addition, because the dichlorosilane and the ethylene in the gas nozzle 31 can be heated by the gas heater that is provided separately from the chamber heater 50, the set temperature of the chamber heater 50 can be low. For this reason, it is possible to reduce a thermal history experienced by each substrate W processed inside the inner tube 11. According to the film forming method of the third example, it is possible to simultaneously reduce the thermal history and improve the reactivities of the dichlorosilane and the ethylene.

In the example illustrated in FIG. 6, the gas nozzle 31 is heated by the gas heater from the time t31 until the film forming process ends, but the timing at which the gas nozzle 31 is heated by the gas heater is not limited thereto. For example, the gas nozzle 31 may be heated by the gas heater at the same timing as the timing at which the gas nozzle 31 supplies the dichlorosilane and the ethylene into the inner tube 11. That is, the gas nozzle 31 may be heated by the gas heater during the period from the time t31 to the time t32 and during the period from the time t33 to the time t34. For example, the gas heater may start heating the gas nozzle 31 before the time t31.

In the example illustrated in FIG. 6, the method of forming the SiOCN film is described, but a SiON film and a SiCN film can also be formed in a similar manner. For example, the SiON film can be formed by atomic layer deposition in which dichlorosilane, ammonia, and ozone are supplied non-simultaneously. For example, the SiCN film can be formed by atomic layer deposition in which dichlorosilane, ethylene, and ammonia are supplied non-simultaneously.

### Experimental Results

### Experiment Ex1

In an experiment Ex1, silicon nitride films were formed by performing the film forming method illustrated in the timing chart of FIG. 4 by the film forming apparatus 1 according to the embodiment under the following conditions 1A and 1B, and thicknesses of the silicon nitride films were measured.

### <Condition 1A>

Dichlorosilane supplying time (a time from the time t11 to the time t12): 10 seconds
Number of ALD cycles: 200
Set temperature of chamber heater 50: 550° C.
Set temperature of gas heater: 800° C.

### <Condition 1B>

Dichlorosilane supplying time: 30 seconds
Number of ALD cycles: 100
Set temperature of chamber heater 50: 550° C.
Set temperature of gas heater: 800° C.

For comparative purposes, silicon nitride films were formed under conditions in which the gas nozzle 31 is not heated by the gas heater (hereinafter referred to as “a condition 1X” and “a condition 1Y”), as opposed to the silicon nitride films formed under the condition 1A and the condition 1B, respectively. The thicknesses of the silicon nitride films were measured.

### <Condition 1X>

Dichlorosilane supply time: 10 seconds
Number of ALD cycles: 200
Set temperature of chamber heater 50: 550° C.
Gas heater: OFF

### <Condition 1Y>

Dichlorosilane supply time: 30 seconds
Number of ALD cycles: 100
Set temperature of chamber heater 50: 550° C.
Gas heater: OFF

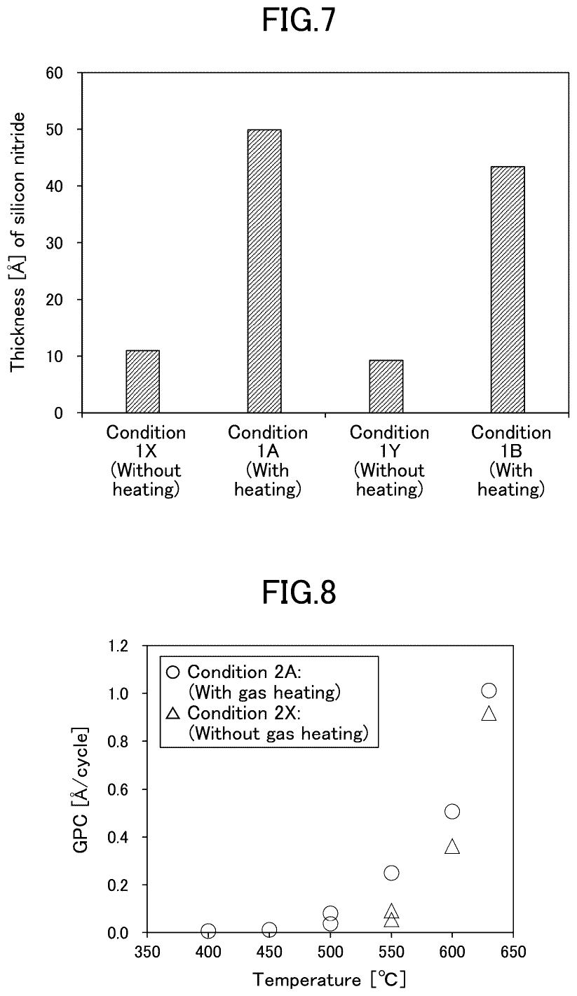

FIG. 7 is a diagram illustrating the measurement results of the thickness of the silicon nitride film. In FIG. 7, the thicknesses [Å] of the silicon nitride films for the cases of the condition 1X, the condition 1A, the condition 1Y, and the condition 1B are illustrated in an order from the left to right.

As illustrated in FIG. 7, it can be seen that the thickness of the silicon nitride film in the case of the condition 1X is 11 Å, whereas the thickness of the silicon nitride film in the case of the condition 1A is 50 Å. As illustrated in FIG. 7, it can also be seen that the thickness of the silicon nitride film in the case of the condition 1Y is 9 Å, whereas the thickness of the silicon nitride film in the case of the condition 1B is 43 Å. From these measurement results, it was confirmed that the film deposition rate when forming the silicon nitride film is improved by using dichlorosilane heated in the gas nozzle 31 by the gas heater.

### Experiment Ex2

In an experiment Ex2, a silicon nitride film was formed by performing the film forming method illustrated in the timing chart of FIG. 4 by the film forming apparatus 1 according to the embodiment under the following condition 2A, and the film deposition rate (in growth per cycle, GPC) of the silicon nitride film was obtained.

### <Condition 2A>

Dichlorosilane supply time: 10 seconds
Number of ALD cycles: 200
Set temperature of chamber heater 50: 400° C. to 650° C.
Set temperature of gas heater: 800° C.

For comparative purposes, a silicon nitride film was formed under a condition in which the gas nozzle 31 is not heated by the gas heater (hereinafter referred to as “a condition 2X”), as opposed to the silicon nitride film formed under the condition 2A. The film deposition rates (GPCs) of the silicon nitride films were obtained.

### <Condition 2X>

Dichlorosilane supply time: 10 seconds
Number of ALD cycles: 200
Set temperature of chamber heater 50: 400° C. to 650° C.
Gas heater: OFF

FIG. 8 is a diagram illustrating the measurement results of the film deposition rate of the silicon nitride film. In FIG. 8, the abscissa indicates the set temperature [° C.] of the chamber heater 50, and the ordinate indicates the GPC [Å/cycle] of the silicon nitride film. In FIG. 8, circular marks represent the measurement results for the condition 2A, and triangular marks represent the measurement results for the condition 2X.

As illustrated in FIG. 8, it can be seen that the film deposition rate of the silicon nitride film when the set temperature of the chamber heater 50 is 500° C. under the condition 2A is substantially the same as the thickness of the silicon nitride film when the set temperature of the chamber heater 50 is 550° C. under the condition 2X. From these measurement results, it was confirmed that by using the dichlorosilane heated in the gas nozzle 31 by the gas heater, a silicon nitride film can be formed at a low temperature and at substantially the same film deposition rate as the case where the dichlorosilane is not heated in the gas nozzle 31.

### Experiment Ex3

In an experiment Ex3, a silicon nitride film was formed by performing the film forming method illustrated in the timing chart of FIG. 4 by the film forming apparatus 1 according to the embodiment under the following condition 3A, and an etching resistance and a stress of the silicon nitride film were evaluated. The etching resistance was evaluated using, as an index, an etching rate (a wet etching rate, WER) when wet etching was performed on the silicon nitride film with diluted hydrofluoric acid having a concentration of 0.25%.

### <Condition 3A>

Dichlorosilane supply time: 10 seconds to 60 seconds
Number of ALD cycles: 200
Set temperature of chamber heater 50: 550° C.
Set temperature of gas heater: 800° C.

For comparative purposes, a silicon nitride film was formed by a plasma ALD in which a supply of dichlorosilane and a supply of plasma generated by exciting ammonia gas by radio frequency (RF) power are alternately performed (hereinafter referred to as “a condition 3X”), as opposed to the silicon nitride film formed under the condition 3A. In addition, the etching resistance and stress of the silicon nitride films were evaluated.

### <Condition 3X>

Set temperature of chamber heater 50: 550° C.

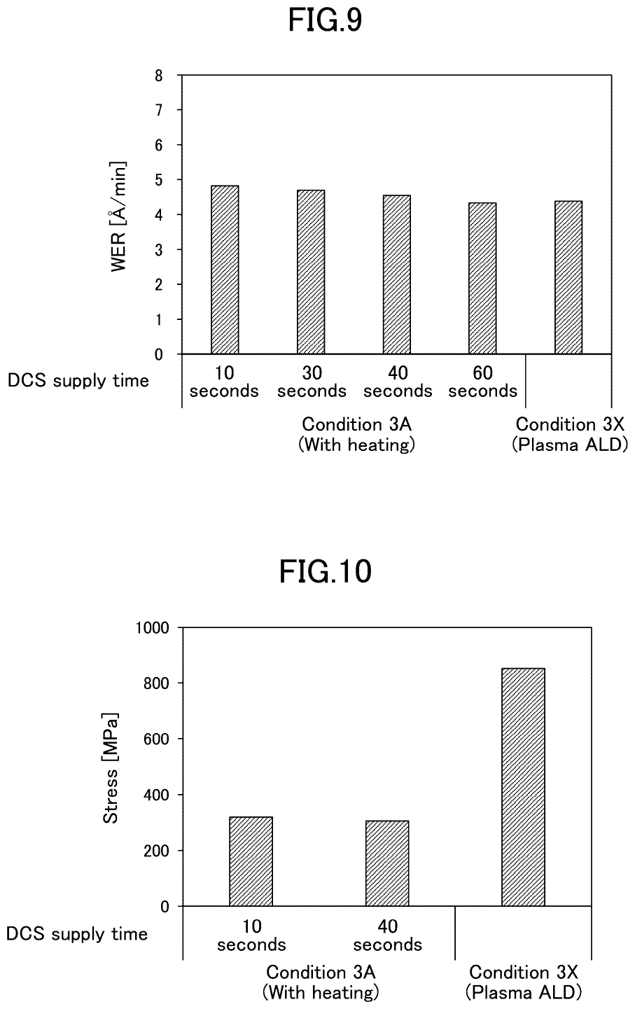

FIG. 9 is a diagram illustrating the measurement results of the WER of the silicon nitride film. In FIG. 9, four graphs on the left side illustrate the WER [Å/min] in the case of the condition 3A, and one graph on the right side illustrates the WER [Å/sec] in the case of the condition 3X.

As illustrated in FIG. 9, when the four left graphs in the case of the condition 3A and the one right graph in the case of the condition 3X are compared, it can be seen that the WERs are substantially the same. From these measurement results, it was confirmed that, by forming the silicon nitride film using the dichlorosilane heated in the gas nozzle 31 by the gas heater, it is possible to obtain substantially the same WER as that obtained in the case where the silicon nitride film is formed by the plasma ALD.

FIG. 10 is a diagram illustrating the measurement results of the stress of the silicon nitride film. In FIG. 10, two graphs on the left side illustrate the stress [MPa] of the silicon nitride film in the case of the condition 3A, and one graph on the right side illustrates the stress [MPa] of the silicon nitride film in the case of the condition 3X.

As illustrated in FIG. 10, it can be seen that the stress of the silicon nitride film is approximately 300 MPa in the case of the condition 3A, whereas the stress of the silicon nitride film is approximately 850 MPa in the case of the condition 3X. From these measurement results, it was confirmed that the stress of the silicon nitride film can be reduced by forming the silicon nitride film using the dichlorosilane heated in the gas nozzle 31 by the gas heater, when compared to the case where the silicon nitride film is formed by the plasma ALD.

The embodiments disclosed herein are to be considered in all respects as illustrative only and non-limiting. The embodiments described above may be omitted, replaced, or modified in various forms without departing from the scope and spirit of the present disclosure.

In the embodiment described above, the case where the first source gas is dichlorosilane is described, but the present disclosure is not limited thereto. The first source gas is a silicon-containing gas, for example. The silicon-containing gas is aminosilane, silane hydride, or halogen-containing silicon, for example. The aminosilane may be diisopropylaminosilane (DIPAS), tris(dimethylamino) silane (3DMAS), bis(tert-butylamino) silane (BTBAS), or a combination thereof. The silane hydride may be monosilane (SiH₄), disilane (Si₂H₆), trisilane (Si₃H₈), tetrasilane (Si₄H₁₀), or a combination thereof. The halogen-containing silicon may be fluorine-containing silicon such as SiF₄, SiHF₃, SiH₂F₂, SiH₃F, or the like, chlorine-containing silicon such as SiCl₄, SiHCl₃, or the like, bromine-containing silicon such as SiHBr₃, SiBr₄, SiH₂Br₂, SiH₂Cl₂, Si₂Cl₆, SiH₃Br, SiH₃Cl, or the like, or a combination thereof.

In the embodiment described above, the case where the second source gas is ethylene is described, but the present disclosure is not limited thereto. The second source gas is a carbon-containing gas, for example. The carbon-containing gas is hydrocarbon, for example. The hydrocarbon may be ethylene (C₂H₄), methane (CH₄), ethane (C₂H₆), propane (C₃H₈), propylene (C₃H₆), acetylene (C₂H₂), or combinations thereof.

In the embodiment described above, the case where the first reaction gas is ammonia is described, but the present disclosure is not limited thereto. The first reaction gas is a gas that reacts with the first source gas to generate a reaction product. The first reaction gas is a nitriding gas, for example. The nitriding gas may be ammonia, diazene (N₂H₂), hydrazine (N₂H₄), monomethylhydrazine (CH₃ (NH) NH₂), or a combination thereof.

In the embodiment described above, the case where the second reaction gas is ozone is described, but the present disclosure is not limited thereto. The second reaction gas is a gas that reacts with the first source gas to generate a reaction product. The second reaction gas is an oxidizing gas, for example. The oxidizing gas may be ozone (O₃), oxygen (O₂), water vapor (H₂O), nitrogen dioxide (NO₂), or a combination thereof.

According to the present disclosure, it is possible to improve a film deposition rate when forming a silicon-containing film at a low temperature.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming method comprising:
loading a plurality of substrates into a processing chamber;
heating an inside of the processing chamber by a chamber heater provided around the processing chamber;
heating a first source gas in a first gas nozzle by a gas heater included in the first gas nozzle, and supplying the heated first source gas from the first gas nozzle into the processing chamber;
supplying a first reactive gas that reacts with the first source gas from a second gas nozzle into the processing chamber; and
repeating a cycle, including the supplying the first source gas and the supplying the first reactive gas, a plurality of times.

2. The film forming method as claimed in claim 1, wherein a set temperature of the gas heater is higher than a set temperature of the chamber heater.

3. The film forming method as claimed in claim 1, wherein the first reactive gas is activated by being heated.

4. The film forming method as claimed in claim 1, wherein:
the first source gas is a silicon-containing gas, and
the first reactive gas is a nitriding gas or an oxidizing gas.

5. The film forming method as claimed in claim 1, further comprising:
heating a second source gas in the first gas nozzle by the gas heater, and supplying the heated second source gas from the first gas nozzle into the processing chamber,
wherein the cycle further includes the supplying the second source gas.

6. The film forming method as claimed in claim 5, wherein:
the first source gas is a silicon-containing gas,
the second source gas is a carbon-containing gas, and
the first reactive gas is an nitriding gas or an oxidizing gas.

7. The film forming method as claimed in claim 1, further comprising:
supplying a second reactive gas that reacts with the first source gas from the second gas nozzle into the processing chamber,
wherein the cycle further includes the supplying the second reactive gas.

8. The film forming method as claimed in claim 7, wherein:
the first source gas is a silicon-containing gas,
the first reactive gas is a nitrogen-containing gas, and
the second reactive gas is an oxygen-containing gas.

9. A film forming apparatus comprising:
a processing chamber configured to accommodate a plurality of substrates;
a chamber heater provided around the processing chamber and configured to heat an inside of the processing chamber;
a first gas nozzle configured to supply a first source gas into the processing chamber; and
a controller, wherein:
the first gas nozzle includes a gas heater configured to heat the first source gas in the first gas nozzle, and
the controller performs a process including:
loading the plurality of substrates into the processing chamber;
heating the inside of the processing chamber by the chamber heater; and
heating the first source gas in the first gas nozzle by the gas heater, and supplying the heated first source gas into the processing chamber by the first gas nozzle,
supplying the first reactive gas into the processing chamber by the second gas nozzle, and
repeating a cycle, including the supplying the first source gas and the supplying the first reactive gas, a plurality of times.
